(19) United States
(12) Patent Application Publication
(10) Pub. No.: US 2015/0107770 A1
(43) Pub. Date: Apr. 23, 2015

(54) SIDE STORAGE UNIT FOR REMOVING FUMES AND MANUFACTURING APPARATUS FOR SEMIONDUCTOR DEVICES HAVING THE SAME

(71) Applicant: SAMSUNG ELECTRONICS CO., LTD., Suwon-si (KR)

(72) Inventors: Hyun-Sun CHOI, Suwon-si (KR); Tae-Hoon KIM, Yongin-si (KR); Jung-Bong YUN, Hwaseong-si (KR); Byeung-Wook CHOI, Hwaseong-si (KR)

(21) Appl. No.: 14/478,334

(22) Filed: Sep. 5, 2014

(30) Foreign Application Priority Data
Oct. 18, 2013 (KR) 10-2013-0124310

(51) Int. Cl. H01L 21/67; H01J 37/32; F24F 7/00

(52) U.S. Cl. CPC H01L 21/67069; F24F 7/00; H01L 21/67184; H01L 21/67201; H01J 37/32899; H01J 37/32733; H01J 37/3244
USPC 156/345.29; 454/339

(57) ABSTRACT

Provided is a side storage unit, including a cleaning chamber to receive a plurality of substrates, the cleaning chamber having a gas supplier to supply therethrough cleaning gases for removing fumes from the substrate, and a plurality of discharge openings to discharge therethrough a mixture of the fumes and the cleaning gases; a plurality of substrate holders arranged on an inner sidewall of the cleaning chamber and supporting the substrates in the cleaning chamber, each of the substrate holders having at least one gas injector connected to the gas supplier to supply the cleaning gases onto a surface of the substrate; and a discharge assembly connected to the discharge openings to discharge the mixture of the fumes and the cleaning gases.

### CROSS-REFERENCE TO RELATED APPLICATION

Korean Patent Application No. 10-2013-0124310, filed on Oct. 18, 2013, in the Korean Intellectual Property Office, and entitled: “Side Storage Unit For Removing Fumes And Manufacturing Apparatus For Semiconductor Devices Having The Same,” is incorporated by reference herein in its entirety.

### BACKGROUND

1. Field

Example embodiments relate to a side storage unit and a manufacturing apparatus having the same, and more particularly, to a side storage unit for an equipment front end module (EFEM) and a manufacturing apparatus for semiconductor devices including the side storage unit.

2. Description of the Related Art

Semiconductor devices may be manufactured through various unit processes, such as a deposition process, a photolithography process and an ion implantation process, that are sequentially performed in series under high vacuum state using respective various source gases.

### SUMMARY

Embodiments may be realized by providing a side storage unit, including a cleaning chamber to receive a plurality of substrates, the cleaning chamber having a gas supplier to supply therethrough cleaning gases for removing fumes from the substrate, and a plurality of discharge openings to discharge therethrough a mixture of the fumes and the cleaning gases; a plurality of substrate holders arranged on an inner sidewall of the cleaning chamber and supporting the substrates in the cleaning chamber, each of the substrate holders having at least one gas injector connected to the gas supplier to supply the cleaning gases onto a surface of the substrate; and a discharge assembly connected to the discharge openings to discharge the mixture of the fumes and the cleaning gases.

The cleaning chamber may include a front portion having an opening through which the substrates pass, a rear portion opposite the front portion and having the discharge holes, and a side portion connected to the front portion and the rear portion and having the gas supplier in a configuration such that a receiving space is defined by the front portion, rear portion and the side portion and the substrates are received in the receiving space.

The gas supplier may include a vertical supplier extending in a vertical direction of the side portion and connected to an external cleaning gas reservoir and a plurality of horizontal suppliers extending from the vertical supplier in a horizontal direction of the side portion in a configuration such that the horizontal suppliers are spaced apart from each other in the vertical direction and correspond to the substrate holders and the gas injector of each substrate holder is connected to a corresponding horizontal supplier.

The vertical supplier may include a cylinder upwardly penetrating the side portion of the cleaning chamber around the rear portion and a plurality of the horizontal suppliers includes a plurality of void branches extending into an inside of the side portion of the cleaning chamber from the cylinder such that the gas injector of each substrate holder is in communication with a void branch corresponding to each substrate holder.

The side storage unit as claimed in claim 2 may further include a heater for heating the cleaning gases in the gas supplier, the heater covering an outer wall of the side portion of the cleaning chamber.

The substrate holder may include a plate structure having a first plate in which at least one first recess is provided and a second plate in which at least one second recess corresponding to the first recess is provided, the first plate and the second plate being in contact with each other such that the at least one first recess and the at least one second recess combined correspond to the at least one gas injector.

The first plate may be integral with the side portion of the cleaning chamber in one body and the second plate is mechanically assembled with the first plate.

The cleaning gases may include inactive gases that are supplied onto the substrate at a volume rate of 75 liter/minute to 85 liter/minute under a temperature of 40° C. to 60° C.

The discharge assembly may include a collector covering the rear portion of the cleaning chamber to collect the mixture of the cleaning gases and the fumes through the discharge holes, a container arranged under the cleaning chamber to receive the mixture of the cleaning gases and the fumes, a discharge line connected to the container to discharge therethrough the mixture outwards and a discharge sensor to detect the mixture in the discharge line.

The discharge sensor may include a differential pressure sensor to detect a flow of the mixture by a pressure variation of the mixture in the discharge line.

The discharge assembly may further include a gas separator to separate cleaning gases from the mixture, a recycling line connected to the gas separator to collect cleaning gases and recycling cleaning gases, and a recovery flow controller installed on the recycling line to control an amount of separated cleaning gases in the recycling line.

The recovery flow controller may include a mesh structure to control a cross sectional flow area of the recycling line and the amount of separated cleaning gases in the recycling line.

The discharge assembly may further include a discharge accelerator having a slender portion at which a cross sectional area of the discharge line may be partially reduced and an air supplier for supplying high pressure air into the slender portion.

Embodiments may be realized by providing an apparatus for manufacturing semiconductor devices, including a substrate processor including at least one process chamber to perform a semiconductor manufacturing process on a semiconductor substrate; a substrate carrier to receive a plurality of the substrates; and a substrate transfer module to transfer the substrate between the substrate processor and the substrate carrier, the substrate transfer module including a load port to position the substrate carrier and a side storage unit to transfer a plurality of processed substrates from the substrate processor and to remove fumes from processed substrates. The side storage unit includes a cleaning chamber arranged at a side of the substrate transfer module to receive a plurality of processed substrates, the cleaning chamber having a gas supplier to supply therethrough cleaning gases for removing fumes from processed substrates and a plurality of discharge openings to discharge therethrough a mixture of the fumes and the cleaning gases; a plurality of substrate holders arranged on an inner sidewall of the cleaning chamber and supporting the processed substrates in the cleaning chamber and having at least one gas injector connected to the gas supplier to inject the cleaning gases onto a surface of the processed substrate; and a discharge assembly connected to the discharge openings to discharge the mixture of the fumes and the cleaning gases.

The substrate processor may include a multi-chamber system having a plurality of process chambers, at least one load-lock chamber connected with the substrate transfer module and at least one transfer chamber arranged between the load-lock chamber and the plurality of the process chambers to transfer the substrates between the load-lock chamber and the process chamber.

The substrate processor may include an etch chamber in which a plasma etching process can be performed.

Embodiments may be realized by providing a side storage unit including a cleaning chamber to receive a plurality of substrates, the cleaning chamber having a gas supplier to supply therethrough cleaning gases for removing fumes from the substrate, and a plurality of discharge openings to discharge therethrough a mixture of the fumes and the cleaning gases, the plurality of discharge openings arranged into a pattern with a larger opening area of discharge openings near an top surface of the cleaning chamber than a bottom surface of the cleaning chamber; and a discharge assembly connected to the discharge openings to discharge the mixture of the fumes and the cleaning gases.

The side storage unit may further comprise a plurality of substrate holders arranged on an inner sidewall of the cleaning chamber and supporting the substrates in the cleaning chamber, each of the substrate holders having at least one gas injector connected to the gas supplier to supply the cleaning gases onto a surface of the substrate, each of the substrate holders having at least one discharge opening corresponding thereto.

Each of the substrate holders may have larger discharge opening corresponding thereto than a substrate holder directly therebeneath.

The cleaning chamber may include a rear portion having the discharge openings and a side portion connected to the rear portion and having the gas supplier.

### BRIEF DESCRIPTION OF THE DRAWINGS

Features will become apparent to those of skill in the art by describing in detail exemplary embodiments with reference to the attached drawings in which:

FIG. 1 illustrates a perspective view illustrating a side storage unit for an EFEM in accordance with an example embodiment;

FIG. 2A illustrates a front view illustrating a chamber of the side storage unit shown in FIG. 1;

FIG. 2B illustrates a side view illustrating a chamber of the side storage unit shown in FIG. 1;

FIG. 3 illustrates an exploded perspective view illustrating the gas supplier of the side storage unit 100 shown in FIG. 1;

FIG. 4A illustrates a partially perspective view of portion A in FIG. 1;

FIG. 4B illustrates an exploded perspective view illustrating the substrate holder shown in FIG. 4A;

FIG. 5 illustrates a structural view illustrating an apparatus for manufacturing semiconductor devices including the side storage unit shown in FIG. 1 in accordance with an example embodiment;

FIG. 6 illustrates a graph showing the concentration of ammonium ions remaining in the cleaning chamber of the an example embodiment of the side storage unit and of the comparative side storage unit; and

FIGS. 7A to 7D illustrate graphs showing the number of particles on the surface of the substrate in the comparative side storage unit and in an example embodiment of the side storage unit.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, like reference numerals refer to like elements throughout, and the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present disclosure.

Unless otherwise defined, all terms (including technical and scientific terms) used herein have the same meaning as commonly understood by one of skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

Side Storage Unit

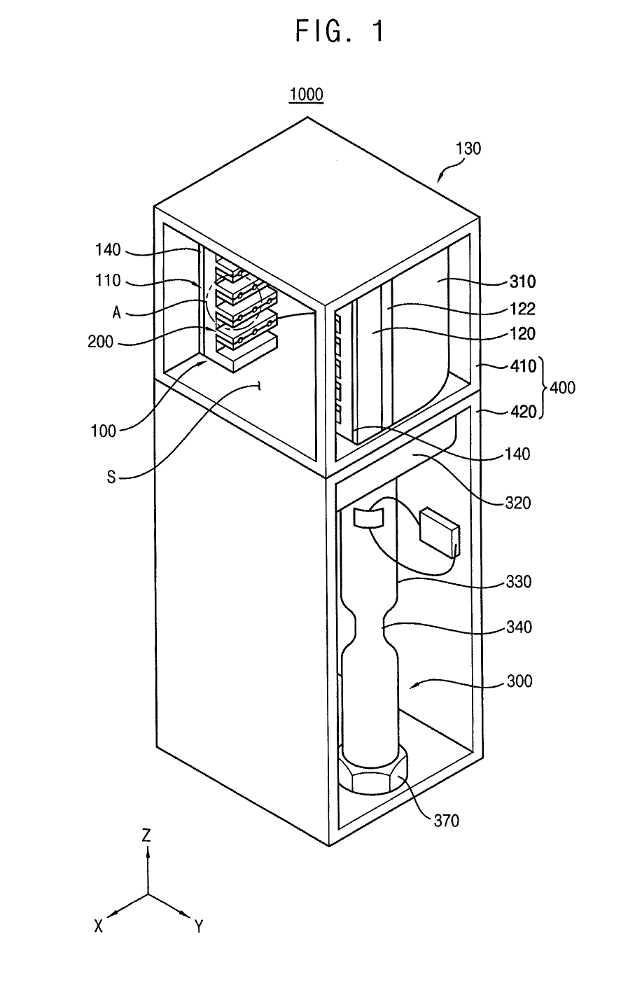

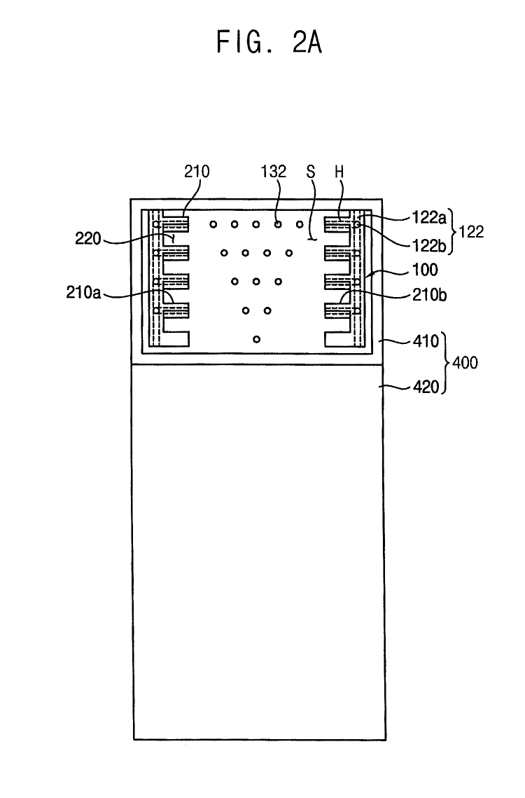

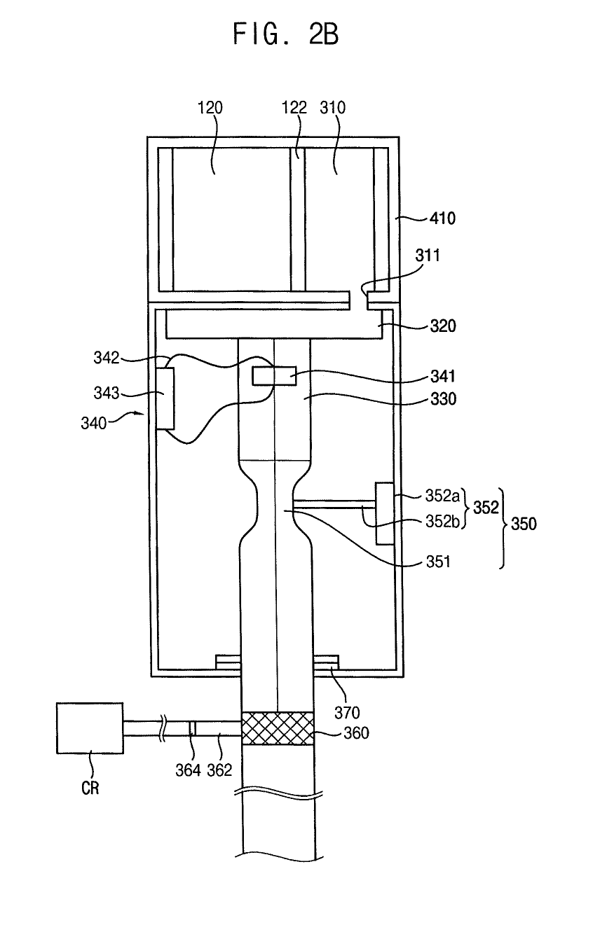

FIG. 1 illustrates a perspective view illustrating a side storage unit for an EFEM in accordance with an example embodiment. FIG. 2A illustrates a front view illustrating a chamber of the side storage unit shown in FIG. 1 and FIG. 2B illustrates a side view illustrating a chamber of the side storage unit shown in FIG. 1.

Referring to FIGS. 1, 2A and 2B, a side storage unit 1000 in accordance with an example embodiment may include a cleaning chamber 100 receiving a plurality of substrates (not shown), a plurality of substrate holders 200 and a discharge assembly 300. The cleaning chamber 100 may include a gas supplier 122 through which cleaning gases for removing fumes from the substrate are supplied and a plurality of discharge openings 132 through which a mixture of the fumes and the cleaning gases are discharged. The substrate holders 200 may be arranged on an inner sidewall of the cleaning chamber 100 and may support the substrates, respectively, in the cleaning chamber 100. Each of the substrate holders 200 may have at least one gas injector H that may be connected to the gas supplier 122 and injects the cleaning gases onto a surface of the substrate. The discharge assembly 300 may be connected to the discharge openings 132 to thereby discharge the mixture of the fumes and the cleaning gases outwards. The cleaning chamber 100, the substrate holder 200 and the discharge assembly 300 may be arranged in a housing 400 including an upper housing 410 and a lower housing 420.

In an example embodiment, the cleaning chamber 100 includes a front portion 110 having an opening through which the substrates may pass, a rear portion 130 opposite to the front portion 110 and having the discharge openings 132, and a side portion 120 that may be connected to the front portion 110 and the rear portion 130 and may have the gas supplier 122. The front portion 110, rear portion 130 and the side portion 120 may define a receiving space S that may be in communication with surroundings through the opening of the front portion 110. The substrates may be inserted into a slot 210, e.g., a gap between a pair of adjacent substrate holders 200, and be supported on the substrate holder 200 in the receiving space S, respectively. A plurality of the substrates may be stacked in the receiving space S of the cleaning chamber 100.

A substrate transfer module (not shown) may be connected to the side storage unit 1000 through the opening of the front portion 110 of the cleaning chamber 100. A unit process for manufacturing a semiconductor device may be completed with respect to the substrate in a process chamber (not shown), and the processed substrate may be unloaded into the substrate transfer module from the process chamber and then may be transferred into the cleaning chamber 100 through the opening of the front portion 110. Each substrate may be inserted into the slot 220 between the substrate holders 200, and a plurality of the processed substrates may be stacked in the receiving space S of the cleaning chamber 100. The fumes may be sufficiently removed from the processed substrate, and the purified processed substrate (hereinafter, referred to as cleaned substrate) may be returned again into the substrate transfer module through the opening of the front portion 110. Then, the cleaned substrate may be stacked into a substrate carrier (not shown) such as a wafer cassette.

The side portion 120 of the cleaning chamber 100 may be connected to a plurality of the substrate holders 200 at the inner sidewall of the side portion 120, and a plurality of the substrates may be positioned on the plurality of the substrates holders 200, respectively. For example, the substrate holder 200 may include a plate structure 210. A plurality of the plate structures 210 may be arranged on the inner sidewalls of the side portion 120 along a vertical direction z of the cleaning chamber 100 at a uniform gap distance. In an example embodiment, the cleaning chamber 100 may include a pair of the side portions 120 facing each other, and the plate structures 210 may be arranged on both inner sidewalls of the side portion 120 that may be referred to as left plate structure 210a and right plate structure 210b, respectively. The left plate structure 210a may face the corresponding right plate structure 210b across the receiving space S in such a configuration that a left edge portion of the substrate may be positioned on the left plate structure 210a and a right edge portion of the substrate may be positioned on the right plate structure 210b in the cleaning chamber 100. A pair of the left and right plate structures 210a and 210b facing each other may function as a single plate structure 210 for supporting a single substrate in the receiving space S. A plurality of the substrates may be stacked in the receiving space S along the vertical direction, i.e., a height, of the cleaning chamber 100 by a plurality of the plate structures 210 arranged along both of the sidewalls of the side portion 120. In an example embodiment, thirty plate structures 210 may be arranged on the side portion 120 along the height of the cleaning chamber 100, and thirty substrates may be received in the cleaning chamber 100 at a time.

The gas supplier 120 may be provided with the side portion 120 of the cleaning chamber 100.

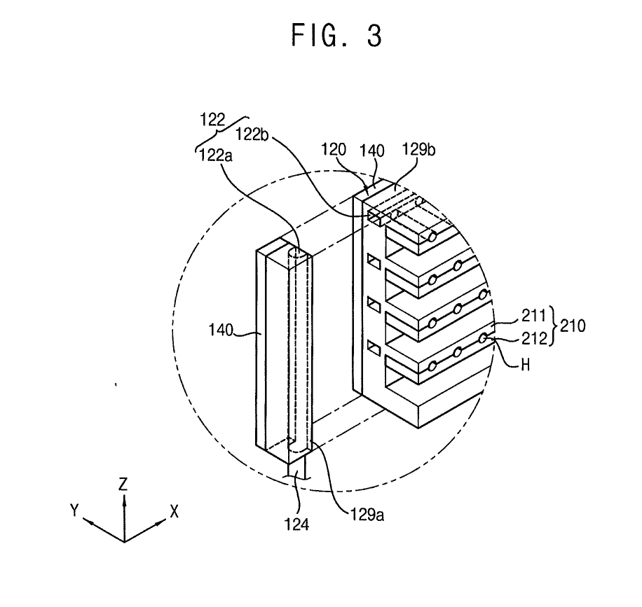

FIG. 3 illustrates an exploded perspective view illustrating the gas supplier of the side storage unit 100 shown in FIG. 1.

Referring to FIG. 3, the gas supplier 122 may include a vertical supplier 122a that may extend in the vertical direction z of the side portion 120 and be connected to an external cleaning gas reservoir CR and a plurality of horizontal suppliers 122b that may extend from the vertical supplier 122a in a first horizontal direction x of the side portion 120 in such a configuration that the horizontal suppliers 122b may be spaced apart from each other in the vertical direction z and correspond to the substrate holders 200, respectively. The gas injector H of each substrate holder 200 may be connected to the corresponding horizontal supplier 122b.

The vertical supplier 122a may include a cylinder upwardly penetrating the side portion 120 of the cleaning chamber 100 around the rear portion 130. In an example embodiment, a pair of the vertical suppliers 122a may be arranged at both of the side portions 120, respectively.

A plurality of the horizontal suppliers 122b may include a plurality of void branches extending into an inside of the side portion 120 of the cleaning chamber 100 from the cylinder along the first horizontal direction x, respectively, and the gas injector H of each plate structure 210 may be in communication with the corresponding void branch.

In an example embodiment, the horizontal supplier 122b may be provided as a branch void penetrating the side portion in the first horizontal direction x and connected to the vertical supplier 122a, and the vertical supplier 122a may be connected to the external cleaning gas reservoir CR via a supply line 124.

The cleaning gases may flow into the vertical supplier 122a through the supply line 124 and then may be diverted into the horizontal suppliers 122b from the vertical supplier 122a. Finally, the cleaning gases may be supplied into the injection holes H of each of the plate structures 210.

In an example embodiment, the side portion 120 may be divided into a first section 129a with which the vertical supplier 122a may be provided and a second section 129b with which the horizontal suppliers 122b may be provided. The first section 129a and the second section 129b may be individually manufactured and then may be assembled into the side portion 120 in such a way that the horizontal suppliers 122b may be in communication with the vertical supplier 122a. For example, the contact faces of the first and the second sections 129a and 129b facing each other may have various configurations and shapes corresponding to each other for sealing the boundary area of the first and the second sections 129a and 129b, and the cleaning gases may be prevented from leaking from the boundary area.

An example embodiment provides the branch cavities and cylinder in the side portion 120 as the gas supplier 122; any other configurations may be provided with the side portion 120 as long as the cleaning gases may be supplied to the respective plate structures 210. For example, additional tubes may be provided in the side portion 120 as the vertical and the horizontal gas suppliers 122a 122b.

Although not shown in the figures, a mass controller (not shown) may be further installed to the vertical supplier 122a, and the mass flow of the cleaning gases diverted to each of the horizontal suppliers 122b may be accurately controlled. The amount of the cleaning gases may be individually controlled according to each of the plate structures 210, and the mass flow of the cleaning gases may be varied at each horizontal supplier 122b from a top portion to a bottom portion of the cleaning chamber 100. The amount of the cleaning gases supplied to a substrate positioned near the top portion of the cleaning chamber 100 may be different from the amount of the cleaning gases supplied to a substrate positioned near the bottom portion of the cleaning chamber 100, and the fumes may be efficiently removed from the substrate.

A heater 140 may be further provided with the cleaning chamber 100. For example, the heater 140 may be arranged on the side portion 120 of the cleaning chamber 100 to cover the outer sidewall of the side portion 120, and the temperature of cleaning gases in the gas supplier 122 may be controlled. The cleaning gases in the gas supplier 122 may be controlled under a constant temperature in the side storage unit 1000.

The substrate may be unloaded to the substrate transfer module from the process chamber, and some of byproduct gases and/or source gases may also be transferred into the substrate transfer module together with the processed substrate in spite of a purge process in the process chamber. The process chamber may be under a low pressure state or a vacuum state at a high temperature and the substrate transfer module may be under an atmospheric pressure at a room temperature, and the byproducts gases and/or source gases may be easily reacted with the moisture and minute particles in air of the substrate transfer module. Various fumes or contaminants may be generated on the processed substrate in the substrate transfer module including the side storage unit 1000. The byproducts and the fumes or contaminants may be varied according to the unit process performed in the process chamber. For example, the substrate transfer module may be controlled at such a restrain temperature at which the reaction of the minute particles and the byproducts gases of the process chamber may be restrained or minimized, smaller fumes or contaminants may be generated on the substrate in the substrate transfer module, and the substrate may be much less contaminated by the fumes in the substrate transfer module, and the cleaning level of the processed substrate in the substrate transfer module may be increased.

For example, the heater 140 may control the cleaning gases at the restrain temperature in the cleaning chamber 100, and the chemical reaction of the minute particles and the byproducts gases resulting from the process chamber may be significantly restrained or prevented in the cleaning chamber 100, the generation of the fumes or contaminants in the cleaning chamber 100 may be prevented or minimized. The cleaning gases may be controlled at the restrain temperature by the heater 140, the fumes may be sufficiently removed from the substrate in the side storage unit 1000, reaction of the minute particles in air and the byproducts resulting from the process chamber in the cleaning chamber 100 may be restrained, and generation of the fumes on the substrate in the cleaning chamber 100 may be minimized. For example, a plasma etching process may be performed in the process chamber, the cleaning gases may be controlled at a temperature of about 40° C. to about 60° C. by the heater 140, and chemical reaction of the minute particles in air and the byproducts of the plasma etching process in the cleaning chamber 100 may be restrained. The fumes on the substrate may be removed from the substrate by the cleaning gases in the cleaning chamber 100, and/or the fumes may hardly be generated on the substrate in the cleaning chamber 100.

For example, the heater 140 may include a heating pack covering a whole outer sidewall of the side portion 120 and generating Joule heat proportional to the applied electrical currents. Any other heating elements would be used in place of the heating pack as long as the cleaning gases may be sufficiently heated.

The rear portion 130 may be connected to the side portion 120 and be opposite to the front portion 110 and a plurality of the discharge openings 132 may be arranged into a regular pattern or shape on a surface. The mixture of the cleaning gases and the fumes may be discharged out of the cleaning chamber 100 through the discharge openings 132. For example, the discharge openings 132 may be arranged in such a configuration that an opening area of an upper portion may be larger than that of a lower portion, so that a greater amount of the mixture of the cleaning gases and the fumes may be discharged through an upper portion of the cleaning chamber 100 rather than a lower portion thereof. In the present example embodiment, the discharge openings 132 may include a plurality of penetration holes penetrating through the rear portion 130 and through which the receiving space S may be in communication with an outside of the cleaning chamber 100. A plurality of the penetration holes may be arranged into a pattern with a greater number of penetration holes near a top surface of the cleaning chamber than a bottom surface of the cleaning chamber 100.

As described hereinafter, the outer sidewall of the rear portion 130 may be covered with a collector 320, the mixture of the cleaning gases and the fumes may be discharged from the receiving space S through the discharge openings 132 and may be collected in the collector 320. The collected mixture may be discharged out of the side storage unit 1000 through a discharge line 330.

As described above, a plurality of plate structures 210 may be arranged on the inner sidewalls of the side portion 120 along the vertical direction z of the cleaning chamber 100 at a uniform gap distance as the plurality of the substrate holders 200. A single substrate may be inserted into each slot 220 between the adjacent plate structures 210 and may be supported by each plate structure 210, and the substrates may be supported by the plate structures 210, respectively. Each of the plate structures 210 may include at least one gas injector H that may be connected to the gas supplier 122 and may inject the cleaning gases onto the substrate.

In an example embodiment, the plate structures 210 may be arranged to correspond to the horizontal gas supplier 122b by one to one, and the gas injector H of the plate structure 210 may be in communication with the corresponding horizontal gas supplier 122b. The cleaning gases in the horizontal gas supplier 122b may be injected onto the substrate supported by the plate structure 210 corresponding to the horizontal gas supplier 122b

The plate structure 210 may be configured into various shapes and structures as long as the gas injector H may be connected to the horizontal gas supplier 122b. For example, the plate structure 210 may include a single plate having at least one penetration hole functioning as the gas injector. In another example, the plate structure 210 may include a pair of plates that may be assembled to provide the penetration hole therein.

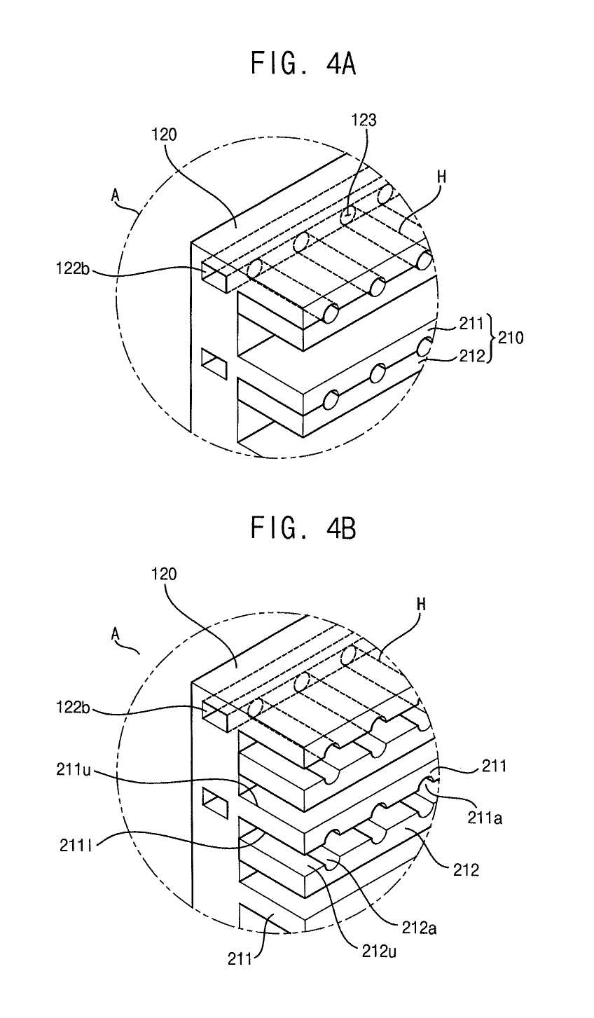

FIG. 4A illustrates a partially perspective view of portion A in FIG. 1 and FIG. 4B illustrates an exploded perspective view illustrating the substrate holder shown in FIG. 4A.

Referring to FIGS. 4A and 4B, the plate structure 210 may include the first plate 211 on which at least one first recess 211a may be provided and the second plate 212 on which at least one second recess 212a corresponding to the first recess 211a may be provided.

For example, the first plate 211 may include a plurality of the first recesses 211a at a lower face 211l and may protrude toward the receiving space S from the side portion 120 of the cleaning chamber 100. The first plate 211 may be prepared integrally with the side portion 120 of the clean chamber 100 in one body. The second plate 212 may include a plurality of the second recesses 212a at an upper face 212u and may be prepared as an additional member independent from the first plate 211. For example, the first recess 211a may extend to the horizontal gas supplier 122b through an inside of the side portion 120.

The second plate 212 may be mechanically assembled with the first plate 211 in such a configuration that the first plate and the second plate may be in contact with each other such that the first recess and the second recess may be combined into the gas injector H penetrating the plate structure 210. A sealing member (not shown) may be further provided on the lower face 211l of the first plate 211 near the first recess 211a and on the upper face 212u of the second plate 212 near the second recess 212a, and leakage of cleaning gases from the gas injector H may be prevented. Further, the configuration and shape of the lower face 211l of the first plate 211 and the upper face 212u of the second plate 212 may be modified in such a structure that the gas injector H may be sufficiently sealed.

For example, the integrality of the first plate 211 and the side portion 120 may sufficiently minimize leakage of cleaning gases between the horizontal gas supplier 122b and the gas injector H. The horizontal gas supplier 122b may be opened through a plurality of side openings 123 and the first plate 211a may be arranged in such a configuration that the first recesses 211a may be positioned at an upper portion of the side openings 123, respectively. The horizontal gas supplier 122b may be exposed according to the shape of the first recess 211a. The second plate 212 may be assembled with the first plate 211 in such a way that the second recesses 212a may be positioned under the first recesses 211a. The space defined by a pair of the first and the second recesses 211a and 212a may be connected to the corresponding side opening 123 of the horizontal gas supplier 122b, and the gas injector H connected to the horizontal gas supplier 122b may be provided.

The first and the second plates 211 and 212 may be mechanically assembled with each other. For example, a joint member such as a bolt may combine the first and the second plates 211 and 212. For another example, mechanical coupling portions (not shown) may be provided on each of the facing lower and upper faces 211l and 212u and the first and the second plates 211 and 212 may be assembled by an interference fit of the coupling portions. Leakage of cleaning gases from the horizontal gas supplier 122b may be significantly minimized as compared with when both of the first and second plates may be assembled to the side portion 120. Further, the upper face 211u of the first plate 211 may be planarized by a surface treatment, and surface damage to the substrate caused by the plate structure 210 may be prevented when the substrate may be stacked in the cleaning chamber 100.

The substrate may be inserted into the slot 220 and positioned on the plate structure 210 in the receiving space S of the cleaning chamber 100, and the cleaning gases may be supplied onto each of the stacked substrates through the gas injector H. The cleaning gases may be uniformly supplied to each of the substrates because the gas injector H may be provided with every plate structure 210. The fumes or contaminants may be removed from each of the substrates in the cleaning chamber 100, and uniformity and quality of the fume removal in the side storage unit 1000 may be increased.

Further, a discharge pressure may be applied to the cleaning chamber 100 through the discharge openings 132 of the rear portion 130, and the mixture of the cleaning gases and the fumes may be discharged out of the cleaning chamber 100 more rapidly and efficiently.

The cleaning process for removing the fumes may be performed on every substrate in the cleaning chamber 100, and contamination of the substrate, for example, due to chemical reaction of the byproduct gases and air in the substrate transfer module, may be prevented.

The cleaning gases may include inactive gases that may sufficiently remove the fumes from the substrate without any chemical reaction in the cleaning chamber 100. For example, the cleaning gases may include nitrogen (N₂) gases and argon (Ar) gases. In addition, the cleaning gases may be supplied onto the substrate at a volume rate of about 75 liter/minute to about 85 liter/minute. The substrate stacked in the cleaning chamber 100 may include minute patterns manufactured in the process chamber, and the minute patterns on the substrate may be damaged by the cleaning process when the cleaning gases may be supplied onto the substrate at an excessively high volume rate. The volume rate of the cleaning gases may be controlled in a rage of about 75 liter/minute to about 85 liter/minute to help minimize such damage.

The mixture of the fumes and the cleaning gases from the cleaning chamber 100 may be discharged out of the side storage unit 1000 through the discharge assembly 300.

For example, the discharge assembly 300 may include a collector 310 arranged to cover the rear portion 130 of the cleaning chamber 100 to thereby collect the mixture of the cleaning gases and the fumes through the discharge openings 132, a container 320 arranged under the cleaning chamber 100 and receiving the mixture of the cleaning gases and the fumes, a discharge line 330 connected to the container 320 and through which the mixture is discharged outwards and a discharge sensor 340 detecting the mixture discharge through the discharge line 330.

The collector 310 may have a concaved open type three-dimensional structure and an outlet 311 may be provided at a bottom thereof. The mixture of the cleaning gases and the fumes may flow out of the collector 310 into the container 320. In an example embodiment, a pair of the outlets 311 may be arranged at right and left portions of the cleaning chamber 100, respectively. The collector 310 may be arranged on the outer sidewall of the rear portion 130 to sufficiently cover the discharge openings 132, and a collection space may be provided between the outer sidewall of the rear portion 130 and an inner sidewall of the collector 310. The mixture may be discharged into the collection space through the discharge openings 132 and may be flowed into the container 320 through the outlets 311 from the collection space.

For example, the cleaning gases may be controlled to flow toward the discharge openings 132, and the mixture of the cleaning gases and the fumes in the receiving space S may be guided to the discharge openings 132. In another example, a discharge pressure may be applied to the mixture in the cleaning chamber 100 via the discharge openings 132, and the discharge speed of the mixture may be increased. In addition, the discharge pressure and the flow control of the cleaning gases may also prevent the mixture from flowing into the substrate transfer module through the opening of the front portion 110.

The container 320 may temporarily contain the mixture of the cleaning gases and the fumes flowed out of the collector 310. For example, the container 320 may be positioned under the cleaning chamber 100, and the fumes removed from the substrate may be guided from the front portion 110 to the rear portion 130 of the cleaning chamber 100 and finally be guided downward with respect to the cleaning chamber 100.

Conventionally, the fumes may be discharged into the container through a bottom hole of the cleaning chamber in a vertical line, and the discharge speed of the fumes may be different between an upper portion and a lower portion of the cleaning chamber. The contamination degree of the substrate due to the fumes may be varied according to the stack position of the substrate in the cleaning chamber. For those reasons, the production yield may be significantly varied between substrate(s) near the top and substrate(s) near the bottom.

However, according to an example embodiment of the side storage unit 1000, the fumes may flow from the front portion 110 to the rear portion 130 not along a vertical direction but along a horizontal direction in the cleaning chamber 100, and the contamination degree of the substrate may be uniform regardless of the stack position in the cleaning chamber 100 and the production yield of the substrate may be uniform with respect to all the substrates stacked in the cleaning chamber 100. The yield production of the substrate(s) near the top may be substantially the same as that of the substrate(s) near the bottom. After discharging from the cleaning chamber 100 along the horizontal direction, the fumes may be collected in the collection space covering the rear portion 130 of the cleaning chamber 100 and then may be discharged downwards into the container 320 that may be positioned under the cleaning chamber 100.

The mixture of the fumes and the cleaning gases may be discharged out of the container 320 through the discharge line 330. The discharge line 330 may include a tube and a pipeline having a sufficient corrosion resistance with respect to the cleaning gases and the fumes.

The discharge sensor 340 may detect the mixture discharge through the discharge line 330. The mixture may not be discharged from the container 320 due to operator errors and/or operation failures of the discharge line 330, the container 320 may be filled with the mixture rapidly, and the mixture may reversely flow into the cleaning chamber 100. A plurality of the substrates may be stacked in the cleaning chamber 100, and the reverse flow of the mixture into the cleaning chamber may cause mass contamination of the substrate. For those reasons, an interruption in the discharge of the mixture from the container 320, hereinafter referred to as discharge interrupt, need be detected in a real time. The discharge sensor 340 may detect in a real time whether the mixture may be discharged through the discharge line 330 from the container 320. The mixture may be detected not to be discharged through the discharge line, and the discharge sensor 340 may generate warning signals. The transfer of the substrate into the cleaning chamber 100 may be stopped instantaneously a warning signal is detected.

For example, the discharge sensor 340 may include a differential pressure sensor 341 positioned on the discharge line 330 and detecting the flow of the mixture by the pressure variation of the mixture in the discharge line 330, a wiring 342 electrically connected with the differential pressure sensor 341 and a discharge controller 343 generating the warning signals and stopping the substrate from transferring into the cleaning chamber 100 when the discharge interrupt may be detected from the pressure variation of the mixture in the discharge line 330. The discharge controller 343 may be positioned on an inner sidewall of the inner housing 420.

In an example embodiment, a discharge accelerator 350 may be arranged on the discharge line 330. For example, the discharge accelerator 350 may include a slender portion 351 at which a cross sectional area of the discharge line 330 may be partially reduced and an air supplier 352 for supplying high pressure air into the slender portion 351. For example, the air supplier 352 may include a pneumatic actuator 352a for generating the high pressure air and a transfer tube for transferring the high pressure air to the slender portion 351. The high pressure air may accelerate the flow of the mixture in the discharge line 330, and the mixture may be discharged from the container 320 more rapidly.

In an example embodiment, a gas separator 360 may be provided to discharge line 330. The gas separator 360 may separate the cleaning gases from the mixture of the fumes and the cleaning gases flowing in the discharge line 330. Then, the separated cleaning gases may be collected to the cleaning gas reservoir CR and the fumes may be discharged out of the side storage unit 1000. The cleaning gases may be supplied into the cleaning chamber 100 through the gas supplier 122 from the cleaning gas reservoir CR and then may be returned into the cleaning gas reservoir CR via the discharge line 330. The cleaning gases may be circulated in a closed circuit and may be recycled in the side storage unit 1000, and the cost of the cleaning gases may be reduced.

In an example embodiment, the gas separator 360 may include various instruments that may separate the cleaning gases from the mixture by using mechanical and chemical properties of the cleaning gases and the fumes. The configurations of the gas separator 360 may be varied according to the fumes and the cleaning gases. The gas separator 360 may be connected to the cleaning gas reservoir CR through a recycling line 362, and the separated cleaning gases may be collected into the cleaning gas reservoir CR via the recycling line 362. A recovery flow controller 364 may be provided with the recycling line 362 and the mass flux of the separated cleaning gases may be controlled in the recycling line 362.

The cleaning time for removing the fumes from the substrate in the cleaning chamber 100 may be determined by the mass flux of the separated cleaning gases in the recycling line 362. A relatively great mass flux in the recycling line 362 may indicate that the cleaning gases may be discharged through the discharge openings 132 and returned into the cleaning gas reservoir CR at a relatively high speed, and may indicate that the cleaning gases may stay in a relatively short time and the fumes may not be sufficiently removed from the substrate in the cleaning chamber 100. For that reason, the recovery flow controller 364 may control the mass flux or the amount of the separated cleaning gases in the recycling line 362 in such a way that the cleaning gases may stay in a sufficient time for removing the fumes from the substrate in the cleaning chamber 100. In an example embodiment, the recovery flow controller 364 may include a mesh structure that may be positioned to be perpendicular to the flow direction of the separated cleaning gases in the recycling line 362. The cross sectional flow area of the separated cleaning gases may be varied or controlled by the mesh structure in the recycling line 362 and the amount of the separated cleaning gases in the recycling line 362 may be controlled by the recovery flow controller 364.

The cleaning chamber 100 including the substrate holders 200 and the discharge assembly 300 may be enclosed by the housing 400, and the chamber 100 and the discharge assembly 300 may be protected from surroundings. For example, the cleaning chamber 100 including the substrate holders 200 and the collector 310 may be enclosed by the upper housing 410 and the container 320, the discharge line 330, the discharge sensor 340 and the discharge accelerator 350 may be enclosed by the lower housing 420. For example, the discharge controller 343 and the pneumatic actuator 352a may be arranged on an inner sidewall of the lower housing 420.

According to example embodiments of the side storage unit, the cleaning gases for removing fumes from the substrate may be supplied to every substrate in the cleaning chamber through the gas injectors that may be provided with each of the substrate holders. No matter how many substrates may be stacked in the cleaning chamber, the fumes may be sufficiently removed from the substrates, and the substrates may be cleaned off individually by the respective gas injector. The substrate may be sufficiently prevented from being contaminated with fumes caused by chemical reaction of byproducts of the process chamber and minute particles in air of the substrate transfer module.

Further, the discharge sensor may automatically detect the discharge interrupt of the mixture in a real time, and the substrate transfer into the side storage unit may be automatically stopped when discharge interrupt of the mixture of the cleaning gases and the fumes is detected. The substrate contamination due to the insufficient discharge of the fumes may be prevented, and the production yield of the semiconductor devices may be increased. For example, the cleaning gases may be separated from the mixture of the cleaning gases and the fumes and then may be returned into the cleaning gas reservoir through the recycling line, and the cleaning gases may be recycled. The recovery flow controller may control the mass flux of the cleaning gases in the recycling line, and the cleaning time for which the cleaning gases may stay in the cleaning chamber may be controlled.

Apparatus for Manufacturing Semiconductor Devices Including the Side Storage

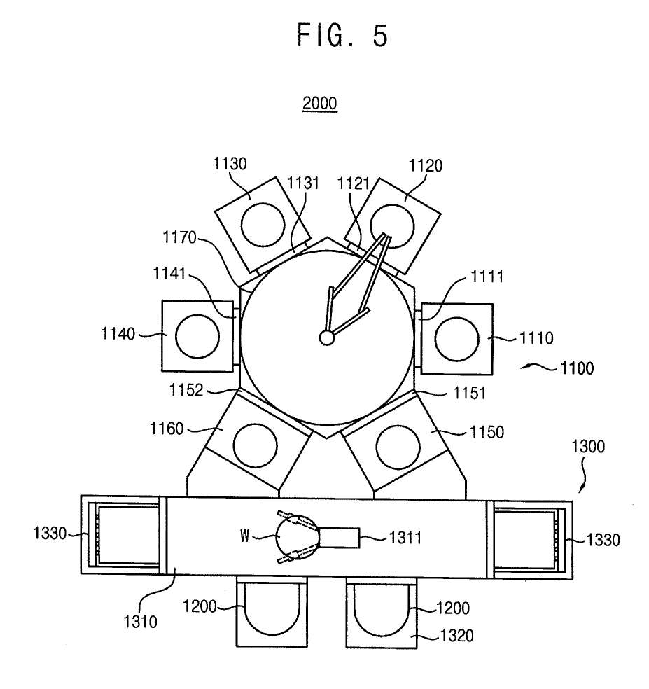

FIG. 5 illustrates a structural view illustrating an apparatus for manufacturing semiconductor devices including the side storage unit shown in FIG. 1 in accordance with an example embodiment.

Referring to FIG. 5, the apparatus 2000 for manufacturing semiconductor devices (hereinafter, referred to as manufacturing apparatus) in accordance with an example embodiment may include a substrate processor 1100 including at least one process chamber for performing a semiconductor manufacturing process to a semiconductor substrate W, a substrate carrier 1200 receiving a plurality of the substrates W, and a substrate transfer module 1300 transferring the substrate W between the substrate processor 1100 and the substrate carrier 1200. The substrate transfer module 1300 may include a load port 1320 at which the substrate carrier 1200 may be positioned and a side storage unit 1330 at which a plurality of processed substrates may be transferred from the substrate processor 1100 and fumes may be removed from the processed substrate.

For example, the substrate processor 1100 may include a plurality of process chambers 1110, 1120, 1130 and 1140 through which a plurality of unit processes may be sequentially performed, a pair of load lock chambers 1150 and 1160 connected to the substrate transfer module 1300 and loading the substrates into the process chambers from the substrate transfer module 1300 and a transfer chamber 1170 transferring the substrates W from the load lock chamber to one of the process chambers. The process chambers 1110, 1120, 1130 and 1140 may be under a relatively high vacuum pressure and the load lock chambers 1150 and 1160 may be under a relatively low vacuum pressure.

The substrate W may include a semiconductor substrate such as a semiconductor wafer, and the process chambers 1110, 1120, 1130 and 1140 may include a chamber for a unit process for manufacturing semiconductor devices such as an etching process and a deposition process. In an example embodiment, the process chambers 1110, 1120, 1130 and 1140 may include chambers for a plasma etching process with respect to a wafer of about 300 mm.

The load lock chamber 1150 and 1160 may be interposed between the process chambers 1110, 1120, 1130 and 1140 under the high vacuum pressure and the substrate transfer module 1300 under an atmospheric pressure, and the load lock chambers 1150 and 1160 may be under the relatively low vacuum pressure between the high vacuum pressure and the atmospheric pressure. The substrate W and pattern structures on the substrate W may be protected from the high pressure variation between the substrate transfer module 1300 and the process chambers.

In an example embodiment, the manufacturing apparatus 2000 may include a cluster type multi-chamber system having a plurality of the process chambers 1110, 1120, 1130 and 1140, the load-lock chambers 1150 and 1160 connected with the substrate transfer module 1300 and at least one transfer chamber 1170 arranged between the load-lock chambers 1150 and 1160 and the plurality of the process chambers 1110, 1120, 1130 and 1140 and transferring the substrates W between the load-lock chambers 1150 and 1160 and the process chambers 1110, 1120, 1130 and 1140.

While an example embodiment provides the cluster type multi-chamber system as the manufacturing apparatus 2000, any other manufacturing system may also be used as the manufacturing apparatus in place of the cluster type multi-chamber system. For example, a single chamber system including a single process chamber and a single load-lock chamber or an inline type multi-chamber system may be used as the manufacturing apparatus 2000 as long as the side storage unit 1000 shown in FIG. 1 may be installed to the substrate transfer module 1300.

A plurality of the substrates W may be stacked in the substrate carrier 1200 and may be transferred to a next manufacturing apparatus. For example, the substrate carrier 1200 may include a front opening unified pod (FOUP) in which the substrates may be stacked with being sealed from surroundings. The substrate carrier 1200 may be positioned at a load port 1320 of the substrate transfer module 1300.

The substrate W may be loaded into the substrate processor 1100 from the substrate carrier 1200 via the substrate transfer module 1300 and the processed substrates may also be stacked back in the substrate carrier 1200 from the substrate processor 1100 via the substrate transfer module 1300. For example, the substrate transfer module 1300 may include an EFEM in which the substrate W may be transferred by a transfer member 1311 such as a robot arm.

The processed substrate may be unloaded into the substrate transfer module 1300 from the substrate processor 1100, and the fumes caused by the reaction between the byproducts of the process chambers and minute particles in air of the substrate transfer module 1300 may be coated or deposited on the processed substrate W. The processed substrate may be transferred into the side storage unit 1330 positioned at an end portion of the substrate transfer module 1300, and the fumes may be removed from the substrate by injecting the cleaning gases onto the substrate. The fumes may be sufficiently removed from the substrate, and the substrate may be transferred to the substrate carrier 1200 from the side storage unit 1330 by the transfer member 1311. In an example embodiment, a pair of the side storage units may be positioned at both end portions of the substrate transfer module 1300, and the efficiency of the fume removal from the substrate may be improved.

The side storage unit 1330 may have substantially the same configurations and functions as the side storage unit 1000 described in detail with reference to FIG. 1. Thus, any further detailed descriptions on the side storage unit 1330 will be omitted.

According to example embodiments of the manufacturing apparatus, the cleaning gases for removing the fumes from the substrate in the side storage unit may be supplied to every substrate in the cleaning chamber through the gas injectors that may be provided with each of the substrate holders. The fumes may be sufficiently removed from the substrates, and the substrates may be cleaned off individually by the respective gas injector. For example, the cleaning gases may be supplied to each of the substrates in the cleaning chamber, and the fume removal from the substrates may be uniformly performed regardless of the stack position of the substrates in the cleaning chamber. The substrate may be sufficiently prevented from being contaminated with fumes caused by chemical reaction of byproducts of the process chamber and minute particles in air of the substrate transfer module, and the production yield of the semiconductor devices may be increased.

Experimental Results of Cleaning Performance of the Side Storage Unit

A plasma etching process was conducted to a plurality of wafers in a process chamber and then the wafers were transferred to the cleaning chamber of the side storage unit shown in FIG. 1 and a comparative side storage unit, respectively, positioned at an end portion of the EFEM. After completing the cleaning process for removing the fumes from the substrate in the cleaning chamber, the concentrations of the byproducts of the etching process remaining in the cleaning chamber were individually measured with respect to each substrate in the side storage unit shown in FIG. 1 and in the comparative side storage unit. In addition, the surface defects caused by the fume were also were individually measured with respect to each substrate in the side storage unit shown in FIG. 1 and in the comparative side storage unit.

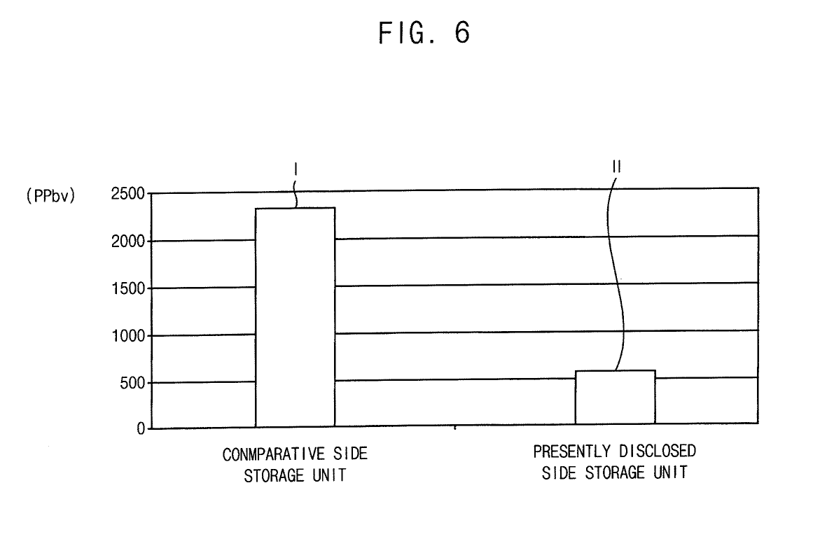

FIG. 6 illustrates a graph showing the concentration of ammonium ions remaining in the cleaning chamber of an example embodiment of the side storage unit and of the comparative side storage unit. The ammonium ions are representative byproducts of the plasma etching process. Graph I indicates the concentration of the ammonium ions in the cleaning chamber of the comparative side storage unit and Graph II indicates the concentration of the ammonium ions in the cleaning chamber of the side storage unit described in detail with reference to FIG. 1 in which the cleaning gases may be supplied from the gas injector at every substrate holder and a plurality of discharge openings may be arranged at the rear portion of the cleaning chamber.

Referring to FIG. 6, the concentration of the ammonium ions in the cleaning chamber of the comparative side storage unit was measured to about 2375 ppbv (particles per billion in volume base), and the concentration of the ammonium ions in the cleaning chamber of the presently disclosed side storage unit was measured to about 583 ppbv. In the comparative side storage unit, the cleaning gases were supplied from a top portion of the EFEM and were discharged together with the fumes through bottom holes of the cleaning chamber in a vertical direction, the cleaning gases were supplied from the gas injector, which was individually installed to each of the substrate holders, and were discharged together with the fumes through the discharge openings at the rear portion of the cleaning chamber in a horizontal direction according to the side storage unit shown in FIG. 1. The experimental results indicate that the gas injector and the discharge openings not at a bottom portion but at the rear portion of the cleaning chamber increase the cleaning effect of the byproducts to about 75%.

When the plasma etching process was performed on a wafer, the injection of the cleaning gases onto every substrate from an end portion of the respective substrate holder may remarkably remove ammonium ions and byproducts of the etching process out of the cleaning chamber, and the cleaning performance in the cleaning chamber of the side storage unit may be significantly improved.

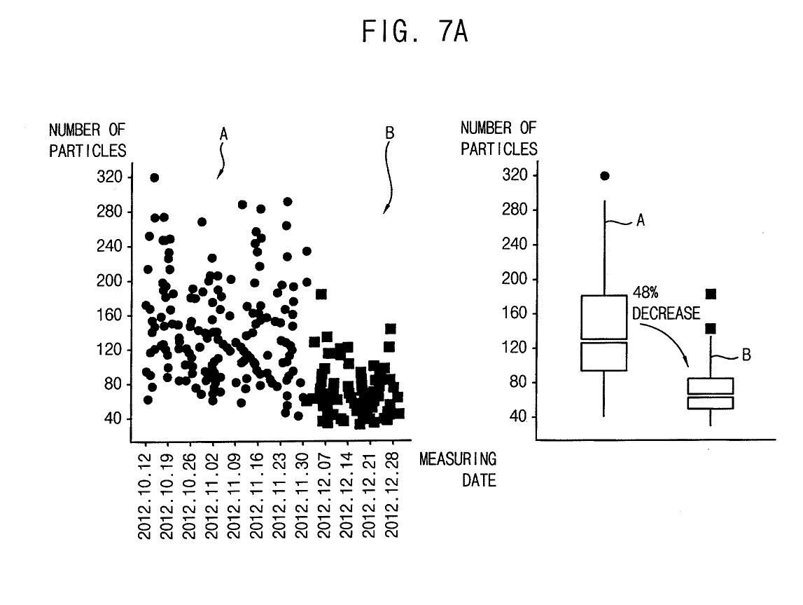

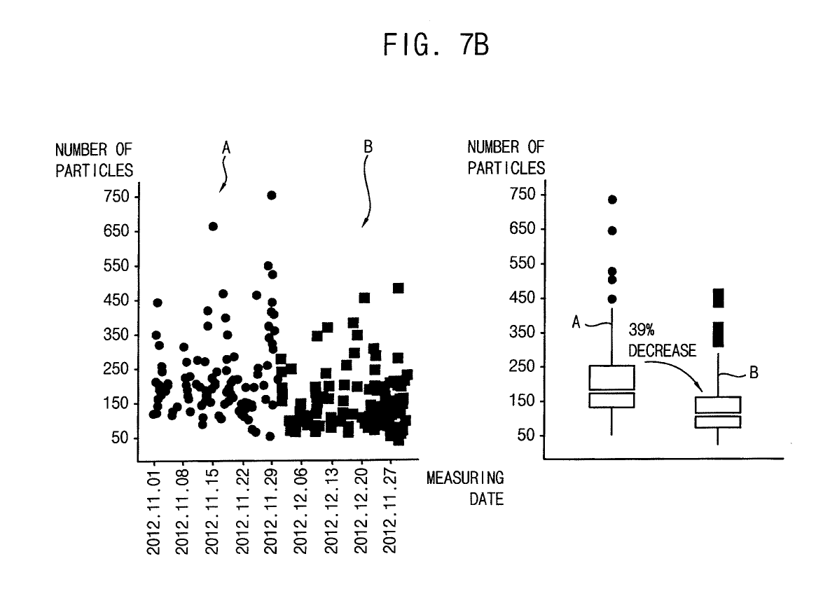

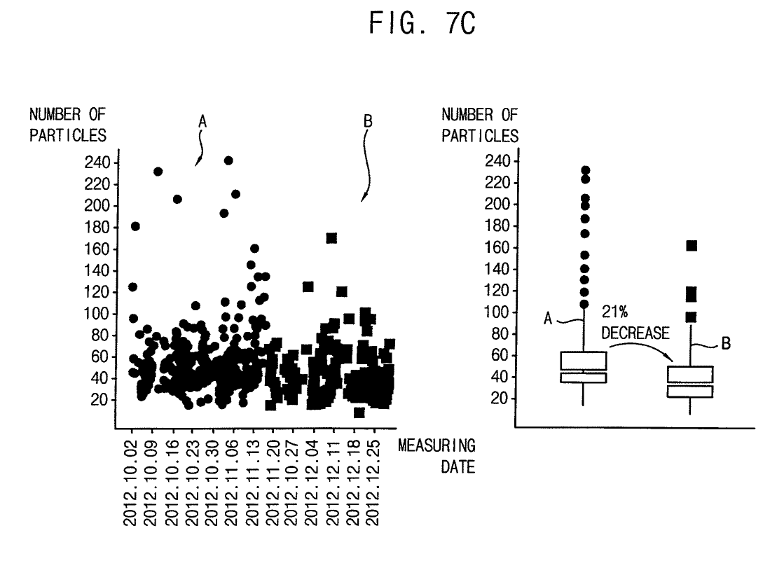

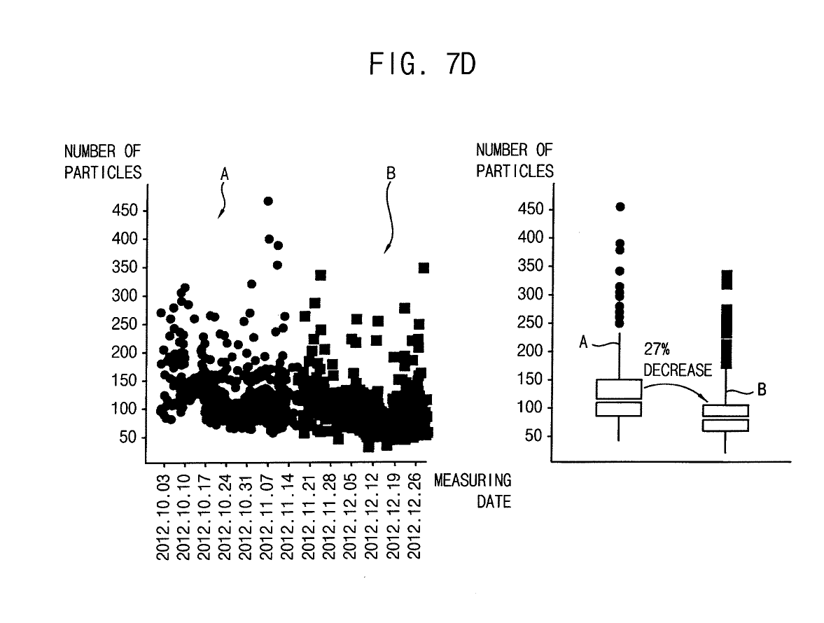

FIGS. 7A to 7D illustrate graphs showing the number of particles on the surface of the substrate in the comparative side storage unit and in an example embodiment of the side storage unit. FIG. 7A illustrates the number of reactive polymers measured from a mask pattern that was formed by a plasma etching process. FIG. 7B illustrates the number of reactive polymers measured from di-cyclohexyl-carbodi (DCC) imide polymer that was planarized by an etch-back process using a plasma etching process. FIG. 7C illustrates the number of reactive polymers measured from a gate pattern of a buried cell array transistor (BCAT) that was formed by a plasma etching process. FIG. 7D illustrates the number of reactive polymers measured from a bit line pattern that was formed by a plasma etching process. The reactive polymer is a representative surface defect caused by the byproducts of the plasma etching process in the EFEM or the side storage unit installed to the EFEM.

In FIGS. 7A to 7D, the graph on the right indicates the number of the reactive polymers measured from a plurality of the wafers at different dates and the graph on the left indicates a statistical distribution diagram of the number of the reactive polymers shown in right graph. A rectangle depicted in the left graph indicates an average number of the reactive polymers. In addition, an A portion of each graph indicates the number of reactive polymers on the substrate of which the fumes were removed in the comparative side storage unit and a portion B of each graph indicates the number of reactive polymers on the substrate of which the fumes were removed in an example embodiment of the presently disclosed side storage unit.

Referring to FIGS. 7A to 7D, the average number of the surface defects of the substrate in an example embodiment of the presently disclosed side storage unit was decreased to about 48%, about 39%, about 21% and about 27% at each plasma etching process compared with that of the substrate in the comparative side storage unit. When the cleaning gases were supplied onto each substrate at an end portion of the each respective substrate holder, the fumes may be significantly removed from the substrate regardless of each process, and the number of the reactive particles may be decreased when completing the plasma etching process.

Table 1 shows production yield of a first substrate in the cleaning chamber and an average production yield of the substrates in the cleaning chamber with respect to the comparative side storage unit and the presently disclosed side storage unit.

TABLE 1

| | Production | Average | |
|---|---|---|---|
| | yield of | production | Difference between |
| | a first | yield of the | the production yield |
| | substrate (%) | substrates (%) | (%) |
| Comparative side | 59.1 | 80.7 | 21.6 |
| storage unit | | | |
| Presently disclosed | 75.6 | 84.4 | 5.0 |
| side storage unit | | | |

When the plasma etching process on the wafers was completed, the wafers were sequentially stacked in the cleaning chamber in such a way that the first wafer was inserted into the first slot nearest the top of the cleaning chamber, the second wafer was inserted into the second slot below the first slot, etc., and the 30^{th} wafer was finally inserted into the 30^{th} slot of the cleaning chamber. The first wafer was exposed to the byproduct gases for a longer time than the 30^{th} wafer, and the first wafer was likely to have much more surface defects than the 30^{th} wafer. The average production yield of the wafers in the FOUP was decisively determined by the production yield of the first wafer.

Therefore, the performance of the side storage needs to be determined in view of a uniform production yield as well as an average production yield. For that reason, the yield gap, the difference between the production yield of the first wafer and the average production yield, is widely used for indicating the performance of the side storage unit.

According to Table 1, when the fumes were removed from the wafer in the comparative side storage unit, the production yield of the first wafer was about 59.1% and the average production yield of the wafers was about 80.7%, which indicates the yield gap of about 21.6.

In contrast, when the fumes were removed from the wafer in the presently disclosed side storage unit, the production yield of the first wafer was about 75.6% and the average production yield of the wafers was about 82.6%, which indicates the yield gap of about 5.0.

Accordingly, the presently disclosed side storage unit increased the yield production of the first wafer to about 16.5% and increased the average production yield of the wafers to about 3.7% as compared with the wafers in the comparative side storage unit. For example, the production yield of the first wafer was improved to about 28% as compared with the production yield of the first wafer in the comparative side storage unit. The cleaning gases supplied from an end portion of the substrate holder in the presently disclosed side storage unit may sufficiently remove the fumes from the first wafer, and the production yield of the first wafer may be remarkably improved. In addition, the cleaning gases were individually supplied to each of the wafers, the fumes were uniformly removed from each wafer, and uniformity of the production yield of the wafers was improved. The presently disclosed side storage unit increased the average production yield of the wafers and decreased the yield gap of the wafers, and uniformity of the production yield was improved.

Example embodiments of the side storage unit may be applied to various apparatus for processing substrates, such as a semiconductor manufacturing apparatus and an liquid-crystal display (LCD) manufacturing apparatus, when the substrate may be contaminated with fumes caused by the byproducts and minute particles in air.

By way of summation and review, after completing each unit process of semiconductor devices manufacturing, the substrate, such as a semiconductor wafer, may be transferred to a neighboring apparatus for the next unit process by using a substrate carrier such as a wafer cassette. The processed substrates are firstly unloaded to an EFEM from a process chamber and then are received into the wafer cassette, e.g., a FOUP, for a transfer to a next apparatus for a next unit process. The processed substrates may be unloaded to the EFEM under an atmospheric pressure, and the residual gases of the respective unit process under a vacuum pressure may also be flowed into the EFEM together with the processed substrate. The residual gases may be combined with moisture and other foreign matters in air of the EFEM, and contaminants or fumes that may adhere to the processed substrates may be generated. The contaminants or the fumes in the EFEM may cause various defects, such as a bridge defect in a pattern structure of the processed substrate, and deterioration of manufacturing yield of the semiconductor devices may be caused.

For those reasons, a side storage unit may be provided with the EFEM and the contaminants or the fumes on the processed substrates may be removed or cleaned up in the side storage unit before the process substrates are received into the wafer cassette. Conventionally, the processed substrate is controlled to stay in the side storage unit for a given time prior to the stack in the wafer cassette.

The comparative side storage unit may be arranged at a side of the EFEM and the air in the EFEM, which may be forcibly circulated by an airflow fan installed at a top of the EFEM and functions as a cleaning gas for removing the fumes from the substrate, may be guided to the side storage unit in which the substrates are stacked, and the fumes may be removed from the substrates by the forcible air flow. Due to the arrangement of the side storage unit with respect to the EFEM, the forcible air flow in the side storage unit is necessarily slanted with respect to the substrates, and the air flow in the side storage unit may not be uniform along every surface of the substrates. As a result, the removal of the contaminants or the fumes may be irregular and non-uniform on all of the substrates in the side storage unit.

For example, the substrates are sequentially stacked downwards from a top portion to a bottom portion in the comparative side storage unit, and the fumes on the substrates at the top portion of the side storage unit are not sufficiently removed as compared with those on the substrates at the bottom portion of the side storage unit, which reduces the production yield of the semiconductor devices and increases an yield gap between the production yield of the upper substrates and the average production yield.

Example embodiments provide a side storage unit in which cleaning gases may be uniformly provided to stacked substrates, and the fumes may be uniformly and efficiently removed from the substrate.

Another example embodiment provides an apparatus for manufacturing the semiconductor devices on which the above side storage unit may be installed.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. In the claims, means-plus-function clauses are intended to cover the structures described herein as performing the recited function and not only structural equivalents but also equivalent structures. Accordingly, it will be understood by those of skill in the art that various changes in form and details may be made without departing from the spirit and scope of the present invention as set forth in the following claims.

What is claimed is:

1. A side storage unit, comprising:
a cleaning chamber to receive a plurality of substrates, the cleaning chamber having a gas supplier to supply therethrough cleaning gases for removing fumes from the substrate, and a plurality of discharge openings to discharge therethrough a mixture of the fumes and the cleaning gases;
a plurality of substrate holders arranged on an inner sidewall of the cleaning chamber and supporting the substrates in the cleaning chamber, each of the substrate holders having at least one gas injector connected to the gas supplier to supply the cleaning gases onto a surface of the substrate; and
a discharge assembly connected to the discharge openings to discharge the mixture of the fumes and the cleaning gases.

2. The side storage unit as claimed in claim 1, wherein the cleaning chamber includes a front portion having an opening through which the substrates pass, a rear portion opposite the front portion and having the discharge openings, and a side portion connected to the front portion and the rear portion and having the gas supplier in a configuration such that a receiving space is defined by the front portion, rear portion and the side portion and the substrates are received in the receiving space.

3. The side storage unit as claimed in claim 2, wherein the gas supplier includes a vertical supplier extending in a vertical direction of the side portion and connected to an external cleaning gas reservoir and a plurality of horizontal suppliers extending from the vertical supplier in a horizontal direction of the side portion in a configuration such that the horizontal suppliers are spaced apart from each other in the vertical direction and correspond to the substrate holders and the gas injector of each substrate holder is connected to a corresponding horizontal supplier.

4. The side storage unit as claimed in claim 3, wherein the vertical supplier includes a cylinder upwardly penetrating the side portion of the cleaning chamber around the rear portion and a plurality of the horizontal suppliers includes a plurality of void branches extending into an inside of the side portion of the cleaning chamber from the cylinder such that the gas injector of each substrate holder is in communication with a void branch corresponding to each substrate holder.

5. The side storage unit as claimed in claim 2, further comprising a heater for heating the cleaning gases in the gas supplier, the heater covering an outer wall of the side portion of the cleaning chamber.

6. The side storage unit as claimed in claim 1, wherein the substrate holder includes a plate structure having a first plate in which at least one first recess is provided and a second plate in which at least one second recess corresponding to the first recess is provided, the first plate and the second plate being in contact with each other such that the at least one first recess and the at least one second recess combined correspond to the at least one gas injector.

7. The side storage unit as claimed in claim 6, wherein the first plate is integral with the side portion of the cleaning chamber in one body and the second plate is mechanically assembled with the first plate.

8. The side storage unit as claimed in claim 1, wherein the cleaning gases include inactive gases that are supplied onto the substrate at a volume rate of 75 liter/minute to 85 liter/minute under a temperature of 40° C. to 60° C.

9. The side storage unit as claimed in claim 1, wherein the discharge assembly includes a collector covering the rear portion of the cleaning chamber to collect the mixture of the cleaning gases and the fumes through the discharge openings, a container arranged under the cleaning chamber to receive the mixture of the cleaning gases and the fumes, a discharge line connected to the container to discharge therethrough the mixture outwards and a discharge sensor to detect the mixture in the discharge line.

10. The side storage unit as claimed in claim 9, wherein the discharge sensor includes a differential pressure sensor to detect a flow of the mixture by a pressure variation of the mixture in the discharge line.

11. The side storage unit as claimed in claim 10, wherein the discharge assembly further includes a gas separator to separate cleaning gases from the mixture, a recycling line connected to the gas separator to collect cleaning gases and recycling cleaning gases, and a recovery flow controller installed on the recycling line to control an amount of separated cleaning gases in the recycling line.

12. The side storage unit as claimed in claim 11, wherein the recovery flow controller includes a mesh structure to control a cross sectional flow area of the recycling line and the amount of separated cleaning gases in the recycling line.

13. The side storage unit as claimed in claim 9, wherein the discharge assembly further includes a discharge accelerator having a slender portion at which a cross sectional area of the discharge line is partially reduced and an air supplier for supplying high pressure air into the slender portion.

14. An apparatus for manufacturing semiconductor devices, comprising;
a substrate processor including at least one process chamber to perform a semiconductor manufacturing process on a semiconductor substrate;
a substrate carrier to receive a plurality of the substrates; and
a substrate transfer module to transfer the substrate between the substrate processor and the substrate carrier, the substrate transfer module including a load port to position the substrate carrier and a side storage unit to transfer a plurality of processed substrates from the substrate processor and to remove fumes from processed substrates,
wherein the side storage unit includes:
a cleaning chamber arranged at a side of the substrate transfer module to receive a plurality of processed substrates, the cleaning chamber having a gas supplier to supply therethrough cleaning gases for removing fumes from processed substrates and a plurality of discharge openings to discharge therethrough a mixture of the fumes and the cleaning gases;
a plurality of substrate holders arranged on an inner sidewall of the cleaning chamber and supporting the processed substrates in the cleaning chamber and having at least one gas injector connected to the gas supplier to inject the cleaning gases onto a surface of the processed substrate; and
a discharge assembly connected to the discharge openings to discharge the mixture of the fumes and the cleaning gases.

15. The apparatus as claimed in claim 14, wherein the substrate processor includes a multi-chamber system having a plurality of process chambers, at least one load-lock chamber connected with the substrate transfer module and at least one transfer chamber arranged between the load-lock chamber and the plurality of the process chambers to transfer the substrates between the load-lock chamber and the process chamber.

16. The apparatus as claimed in claim 14, wherein the substrate processor includes an etch chamber in which a plasma etching process can be performed.

17. A side storage unit, comprising:
a cleaning chamber to receive a plurality of substrates, the cleaning chamber having a gas supplier to supply therethrough cleaning gases for removing fumes from the substrate, and a plurality of discharge openings to discharge therethrough a mixture of the fumes and the cleaning gases, the plurality of discharge openings arranged into a pattern with a greater opening area of discharge openings near an top surface of the cleaning chamber than a bottom surface of the cleaning chamber; and
a discharge assembly connected to the discharge openings to discharge the mixture of the fumes and the cleaning gases.

18. The side storage unit as claimed in claim 16, further comprising:
a plurality of substrate holders arranged on an inner sidewall of the cleaning chamber and supporting the substrates in the cleaning chamber, each of the substrate holders having at least one gas injector connected to the gas supplier to supply the cleaning gases onto a surface of the substrate, each of the substrate holders having at least one discharge opening corresponding thereto.

19. The side storage unit as claimed in claim 17, wherein each of the substrate holders has larger discharge opening corresponding thereto than a substrate holder directly therebeneath.

20. The side storage unit as claimed in claim 18, wherein the cleaning chamber includes a rear portion having the discharge openings and a side portion connected to the rear portion and having the gas supplier.
